(19) United States
(12) Patent Application Publication
(10) Pub. No.: US 2026/0171280 A1
(43) Pub. Date: Jun. 18, 2026

(54) METHOD OF MAKING A THULIUM-171 DOPED BETAVOLTAIC BATTERY USING ERBIUM DOPANTS

(71) Applicant: The Government of the United States of America, as represented by the Secretary of the Navy, Arlington, VA (US)

(72) Inventors: James S. Lundh, Fairfax, VA (US); Marko J. Tadjer, Gaithersburg, MD (US); Karl D. Hobart, Alexandria, VA (US); Bernard F. Phlips, Great Falls, VA (US); Alan G. Jacobs, Rockville, MD (US)

(73) Assignee: The Government of the United States of America, as represented by the Secretary of the Navy, Arlington, VA (US)

(21) Appl. No.: 19/386,346

(22) Filed: Nov. 12, 2025

Related U.S. Application Data
(60) Provisional application No. 63/735,417, filed on Dec. 18, 2024.

(51) Int. Cl. G21H 1/04; H01L 21/425; H01M 4/48

(52) U.S. Cl. CPC G21H 1/04; H01M 4/48; H10P 30/202

(57) ABSTRACT

Betavoltaic batteries and methods of making the same are provided. In embodiments, a method of making a thulium-171 electrically active betavoltaic battery includes: providing a starting semiconductor including a semiconductor material layer doped with a stable non-radioactive isotope erbium-170; irradiating the starting semiconductor with thermal neutrons, thereby causing conversion of at least a portion of the stable non-radioactive isotope erbium-170 to a radioisotope erbium-171, resulting in an intermediate semiconductor; and holding the intermediate semiconductor in a radiation safe environment for a period of time necessary for a predetermined amount of the erbium-171 to transform to a radionuclide thulium-171 via natural beta decay, thereby resulting in a final semiconductor, wherein the semiconductor material layer acts as both an electron emitter and an electron absorber simultaneously.

### CROSS-REFERENCE TO RELATED APPLICATIONS

This Application is a Nonprovisional of, and claims the benefit of priority under 35 U.S.C. § 119 based on, U.S. Provisional Patent Application No. 63/735,417 filed Dec. 18, 2024. The Provisional Application and all references cited herein are hereby incorporated by reference into the present disclosure in their entirety.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; nrltechtran@us.navy.mil, referencing Navy Case No. 212316-US2.

### BACKGROUND OF THE INVENTION

Aspects of the present invention relate generally to betavoltaic batteries and, more particularly, to thulium-171 (¹⁷¹Tm) doped semiconductor betavoltaic batteries.

In general, a battery is a source of electric power derived from chemical energy. A betavoltaic device or betavoltaic battery is a type of nuclear battery which generates electric current from beta particles (electrons) emitted from a radioactive source (i.e., the emitter), using semiconductor junctions (i.e., the absorber). Betavoltaic semiconductor devices use a non-thermal conversion process, ionizing electron-hole pairs produced by beta particles traversing the semiconductor absorber.

The concept of betavoltaic sources is essentially unexplored for gallium oxide (Ga₂O₃), not only because of its relative novelty and scarcity, but also because theoretical studies focusing on source/absorber coupling have shown more promising efficiencies for diamond and cubic boron nitride. While this may be the case, Ga₂O₃ bulk and epitaxial growth has the inherent capability to incorporate a variety of impurities, both intentional and unintentional. From a betavoltaic perspective, Ga₂O₃ is attractive because of its relatively good tolerance to electron irradiation and potentially good tolerance to gamma irradiation at moderate energies.

Monoclinic β-Ga₂O₃ technology has experienced rapid development in recent years. After initial growth demonstrations, melt grown 100-millimeter (mm) diameter Ga₂O₃ substrates have been commercialized. Substrates have been grown using techniques such as edge-defined, film-fed (EFG) growth, Czochralski (CZ), float-zone (FZ), and vertical Bridgman (VB). Commercial epitaxial growth techniques have also resulted in 1-10 micron (m) thick epitaxial layers of high quality, suitable for vertical diode demonstrations in the 5-8 kilovolt (kV) breakdown voltage range. Domestic production of semi-insulating (010) Ga₂O₃ substrates has been scaled up to 2-inch by Northrop Grumman Synoptics and Luxium using Czochralski and EFG techniques, respectively. The ultra-wide bandgap of β-Ga₂O₃ (4.6-4.9 electron-volts) results in a high critical field of 6-8 megavolts per centimeter (MV/cm) and has also enabled lateral and vertical transistor devices potentially suitable for radio frequency and high voltage power switching. In the frequency domain, Ga₂O₃ devices face performance challenges due to the low mobility and low thermal conductivity of Ga₂O₃. For high power electronics, the main challenge is the development of thick, low-doped, defect-free buffer layers for electric field blocking in the off state.

### SUMMARY OF THE INVENTION

In a first aspect of the invention, there is a method including: providing a starting semiconductor including a semiconductor material layer doped with a stable non-radioactive isotope erbium-170; irradiating the starting semiconductor with thermal neutrons, thereby causing conversion of at least a portion of the stable non-radioactive isotope erbium-170 to a radioisotope erbium-171, resulting in an intermediate semiconductor; and holding the intermediate semiconductor in a radiation safe environment for a period of time necessary for a predetermined amount of the erbium-171 to transform to a radionuclide thulium-171 via natural beta decay, thereby resulting in a final semiconductor, wherein the semiconductor material layer acts as both an electron emitter and an electron absorber simultaneously. In implementations, the source of the erbium-170 is a naturally occurring source (e.g., erbium(III) oxide (Er₂O₃)). Alternatively, the source of the erbium-170 may be isotopically pure erbium 170. In embodiments, the semiconductor material layer is selected from the group consisting of: diamond, erbium oxide (Er₂O₃), aluminum nitride (AlN), aluminum gallium nitride (AlGaN), gallium nitride (GaN), silicon carbide (SiC), gallium oxide (Ga₂O₃), sapphire (Al₂O₃), aluminum gallium oxide ((AlₓGa₁₋ₓ)₂O₃), zinc oxide (ZnO), and silicon (Si). In one example, the semiconductor material layer comprises beta gallium oxide (β-Ga₂O₃), and the method further includes growing the semiconductor material layer with the stable non-radioactive isotope erbium-170. The β-Ga₂O₃ may be iridium-free.

In embodiments, the semiconductor material layer is within a semiconductor device including one or more diodes. In implementations, a diode includes an anode fabricated at a first surface of the semiconductor material layer and a cathode fabricated at a second surface of the semiconductor material layer. The method may further include a process of annealing the final semiconductor to repair crystal damage in the semiconductor material layer caused by the irradiation. In aspects of the invention, the starting semiconductor includes one or more additional layers, different from the semiconductor material layer, that act as electron absorbers. For example, the starting semiconductor may include an N-type electron absorber layer of gallium nitride. In implementations, the starting semiconductor further includes a P-type absorber layer selected from P-type Si, diamond, GaN, AlGaN, AlN, SiC, nickel oxide (NiO), chromium oxide (Cr₂O₃), chromium manganate (Cr₂MnO₄), cuprous oxide (CuO, Cu₂O, etc.), and other suitable P-type semiconductors. Those skilled in the art would recognize that certain P-type semiconductors are safe to introduce into a thermal neutron flux, i.e., their irradiation and subsequent neutron capture would not produce undesirable isotope activity upon decay.

In another aspect of the invention, there is an electrically inactive betavoltaic battery device or battery precursor including: a semiconductor material layer including a stable non-radioactive isotope erbium-170, and one or more diodes incorporating the semiconductor material layer, wherein the electrically inactive betavoltaic battery device is configured to be transformed into an electrically active betavoltaic battery upon irradiation with thermal neutrons. In implementations, the semiconductor material layer is selected from the group consisting of: diamond, Er₂O₃, AlN, AlGaN, GaN, SiC, Ga₂O₃, Al₂O₃, (AlₓGa₁₋ₓ)₂O₃, ZnO, and Si. In one example, the semiconductor material layer comprises β-Ga₂O₃. The device may further include an N-type and/or P-type absorber layer.

In another aspect of the invention, there is a betavoltaic battery device including: a semiconductor material layer including a radioactive isotope thulium-171, and one or more diodes incorporating the semiconductor material layer, wherein the semiconductor material layer acts as both an electron emitter and an electron absorber simultaneously. In implementations, the semiconductor material layer is selected from the group consisting of: diamond, Er₂O₃, AlN, AlGaN, GaN, SiC, Ga₂O₃, Al₂O₃, (AlₓGa₁₋ₓ)₂O₃, ZnO, and Si. In one example, the semiconductor material layer comprises β-Ga₂O₃. In implementations, the device further includes at least one N-type or P-type absorber layer.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1 shows an exemplary inactive betavoltaic battery device converting to an active betavoltaic battery in accordance with embodiments of the invention.

FIG. 2 shows the device and battery of FIG. 1 in accordance with embodiments of the invention, wherein the semiconductor is gallium (III) oxide.

FIGS. 3A-3F show alternative embodiments of the inactive betavoltaic battery device and active betavoltaic battery of FIG. 2.

FIG. 4 shows a flowchart of an exemplary method in accordance with aspects of the present invention.

### DETAILED DESCRIPTION

Aspects of the present invention relate generally to betavoltaic batteries and, more particularly, to thulium-171 (¹⁷¹Tm) doped betavoltaic batteries. Implementations of the invention provide a method of making a ¹⁷¹Tm-doped electrically active gallium oxide (Ga₂O₃) betavoltaic battery. In embodiments, a method starts with an electrically inactive betavoltaic battery device (hereafter inactive device) having one or more diodes incorporating a semiconductor material layer including a stable non-radioactive isotope erbium-170 (¹⁷⁰Er, 14.91 percent natural abundance). The inactive device is irradiated with thermal neutrons, thereby causing the conversion of at least a portion of the stable non-radioactive isotope ¹⁷⁰Er to a radioisotope erbium-171 (¹⁷¹Er). This intermediate device is then held in a radiation safe environment for a period of time necessary for a predetermined amount (e.g., at least 90%) of the ¹⁷¹Er isotope to transform to the radionuclide ¹⁷¹Tm via natural beta decay, thereby resulting in a ¹⁷¹Tm-doped electrically active betavoltaic battery. In embodiments, electron-hole pair generation originates from in situ beta particle emission within a Ga₂O₃ semiconductor crystal, which acts both as emitter and absorber simultaneously. This contrasts with prior betavoltaic battery structures with ex situ deposited beta irradiation coatings over semiconductor absorber layers.

As noted above, implementations of the invention utilize thermal neutron irradiation of erbium (Er), a rare-earth Lanthanide. Er has five observationally stable isotopes: ¹⁶²Er (0.139%), ¹⁶⁴Er (1.60%), ¹⁶⁶Er (33.5%), ¹⁶⁷Er (22.9%), ¹⁶⁸Er (27.0%), and ¹⁷⁰Er (14.9%). The stable isotope erbium-170 (¹⁷⁰Er), which has a thermal neutron capture cross-section of approximately 8 barns (b), captures a neutron to become erbium-171 (¹⁷¹Er). The isotope ¹⁷¹Er then decays to ¹⁷¹Tm via beta decay with a half-life of 7.5 hours. In other words, within about a week ¹⁷¹Er goes through about 22 half-lives and the ¹⁷¹Er concentration has decreased to ˜0.00002% of its original concentration. The isotope ¹⁷¹Tm is a pure beta emitter with a half-life of 1.92 years. This makes ¹⁷¹Tm an excellent candidate for betavoltaic applications.

Thermal neutron reactions by the stable isotopes of nitrogen-14 (¹⁴N), nickel-62 (⁶²Ni), krypton-84 (⁸⁴Kr), strontium-88 (⁸⁸Sr), cadmium-112 (¹¹²Cd), iridium-191 (¹⁹¹Ir), and potentially other stable isotopes, can produce radionuclides such as carbon-14 (¹⁴C), ⁶³Ni, ⁸⁵Kr, ⁹⁰Sr, ¹¹³Cd, and ¹⁹²Ir, respectively. Both ¹⁴C and ⁶³Ni are known pure beta emitters with reasonably low energy. The isotopes ⁸⁵Kr, ⁹⁰Sr are also beta emitters but are commonly dismissed for betavoltaics as being too energetic for use with common semiconductors (e.g., Si and SiC). The isotopes ¹¹³Cd and ¹⁹²Ir have high energy beta decay but are also gamma emitters, to which Ga₂O₃ may exhibit reasonable tolerance, especially in the case of ¹¹³Cd whose gamma decay is only due to an isomeric transition. No technology is currently known which can harness the potentially ˜10× higher beta decay energy of ¹¹³Cd (E_{avg}=185.4 kiloelectron volt (keV)) and ⁹⁰Sr/yttrium-90 (⁹⁰Y) (E_{avg}=195.8 keV), compared to the commonly used beta sources of hydrogen-3 (³H) (E_{avg}=5.7 keV), ¹⁴C (E_{avg}=49.5 keV) and ⁶³Ni (E_{avg}=17.4 keV). At these energy levels, Ga₂O₃ should be tolerant to electron irradiation. Electron irradiation at 1.5-2 MeV energy levels have been shown via electron paramagnetic resonance techniques to induce gallium vacancy related defects that typically degrade Schottky barrier diode performance (on-resistance, on/off ratio, reverse bias current, etc.). Thus, any Ga vacancy and related point defects generated by the radionuclide decay paths will cause some degradation to the betavoltaic cell operation. In implementations, some approach for removing point defects (e.g., via thermal annealing) may be required.

The main disadvantage of the aforementioned elements in this case is their natural occurrence in multiple stable isotopes. This would require doping of the host semiconductor with isotopically pure elements, which is extremely expensive. Erbium also occurs in multiple stable isotopes, and only the heaviest one (¹⁷⁰Er) is of interest for betavoltaic applications. Isotopically pure ¹⁷⁰Er is also very expensive (currently about $9000 per gram). However, neutron irradiation of natural Er will result in the production of four unstable isotopes of Er: ¹⁶³Er, ¹⁶⁵Er, ¹⁶⁹Er, and ¹⁷¹Er (radioisotope of interest), as long as only single neutron capture is considered.

The isotope ¹⁶³Er is produced from ¹⁶²Er via single neutron capture, which is only 0.139% abundant and has a thermal neutron capture cross section of about 19 b. ¹⁶³Er decays with 75-minute half-life via 100 percent electron capture process to holmium-163 (¹⁶³Ho), which in turn decays with a 4570-year half-life via 100 percent electron capture to stable dysprosium-163 (¹⁶³Dy), with average energy of 2.55 keV (maximum gamma energy produced during this decay is 1.113 MeV). The short half-life of ¹⁶³Ho allows decay while in a radiation safe storage location, while the long half-life of ¹⁶³Dy leads to low or negligible activity.

The isotope ¹⁶⁵Er is produced from ¹⁶⁴Er via single neutron capture, which is 1.6% abundant and has thermal neutron capture cross section of about 13 b. In turn, ¹⁶⁵Er decays with a 10.36 hour half-life via 100 percent electron capture process to stable holmium-165 (¹⁶⁵Ho) with average decay energy of 376.3 keV. The short half-life of ¹⁶⁵Er allows decay while in a radiation safe storage location.

The isotope ¹⁶⁹Er is produced from ¹⁶⁸Er via single neutron capture, which is 27% abundant and has thermal neutron capture cross section of about 2.74 b. ¹⁶⁹Er decays with 9.392 day half-life via 100 percent beta decay process to stable ¹⁶⁹Tm with average decay energy of 351.3 keV.

Therefore, naturally abundant Er or erbium oxide (Er₂O₃) can be irradiated via primarily thermal neutrons and upon sufficient neutron dose a reasonable quantity of ¹⁷¹Tm will be produced from the 14.9% abundance of ¹⁷¹Er in the sample. The as-produced ¹⁷¹Tm or ¹⁷¹Tm₂O₃ can be then incorporated into a host semiconductor crystal such as β-Ga₂O₃ via standard crystal growth techniques such as the CZ, VB, or EFG techniques. ¹⁷¹Tm is a well-known pure beta emitter with a half-life of 1.92 years, decaying to stable ytterbium-171 (¹⁷¹Yb), allowing for a Ga₂O₃:¹⁷¹Tm Ga₂O₃:¹⁷¹Tm₂O₃ betavoltaic device to be developed, potentially without isotopic enrichment of the Er dopants.

Advantageously, embodiments of the invention allow stable isotopes to be introduced into a semiconductor (e.g., Ga₂O₃) at precise quantities via doping near carrier generation sites where beta-electrons are needed, thus eliminating the need for coating the semiconductor device with a beta irradiation source and improving the conversion efficiency of the semiconductor device. Additionally, Er₂O₃ is a low-cost commercially available oxide powder with 4N purity (a purity of 99.99%), which can be alloyed into a host Ga₂O₃ crystal during melt growth. The strong polaron effects in Ga₂O₃ leading to the self-trapping of holes means that any generated holes will be trapped almost immediately, resulting in excess electron concentration available for transport upon the application of an electric field. Another advantage of implementations of the invention is the scalability of Ga₂O₃ crystal growth, such as 4-inch diameter Ga₂O₃ using EFG or 6-inch diameter Ga₂O₃ using the VB process. The large diameter Ga₂O₃ wafers and thick epitaxial Ga₂O₃ layers offer significant technological advantage in the collector area.

### Exemplary Betavoltaic Devices

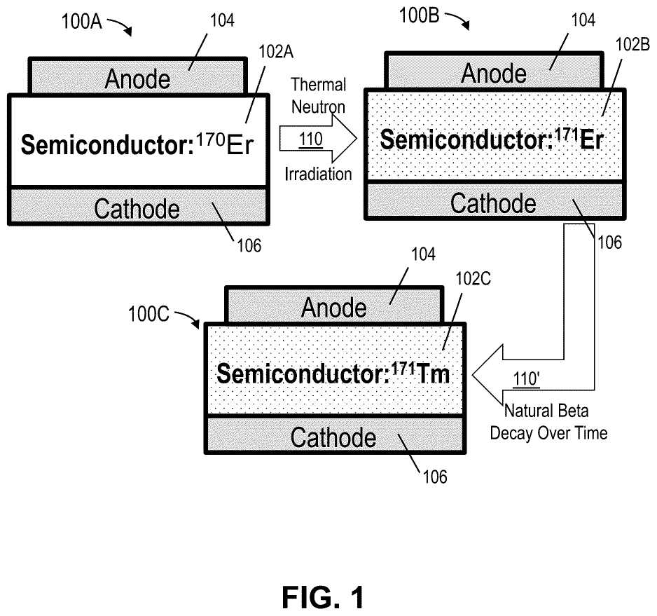

FIG. 1 is a diagram illustrating a method of making a betavoltaic device according to embodiments of the invention. Initially, a starting semiconductor device 100A is provided, including a semiconductor 102A having one or more layers, an anode 104 and a cathode 106. In implementations, the starting semiconductor device 100A is an inactive betavoltaic battery device 100C or a precursor to an active betavoltaic battery device 100C. In embodiments, the semiconductor 102A includes a layer of Ga₂O₃ doped with the stable isotope ¹⁷⁰Er.

The starting semiconductor device 100A is subjected to thermal neutron irradiation at 110, which results in an intermediate semiconductor device 100B, including a semiconductor 102B. In embodiments, the isotope ¹⁷⁰Er in the semiconductor 102A is converted to the first unstable isotope (radionuclide) ¹⁷¹Er in the semiconductor 102B, resulting in an intermediate semiconductor 102B doped with ¹⁷¹Er. The ¹⁷¹Er doped semiconductor 102B is allowed to decay naturally via beta decay at 110′, which results in the ¹⁷¹Er decaying to the second radionuclide ¹⁷¹Tm. Thus, an active betavoltaic battery device 100C is created including a semiconductor 102C doped with the pure beta emitter ¹⁷¹Tm, which has a half-life of 1.92 years. In embodiments, the active betavoltaic battery device 100C comprises Ga₂O₃ doped with ¹⁷¹Tm.

Advantageously, implementations of the invention enable production of a stable electrically inactive betavoltaic battery device (e.g., 100A) in a conventional cleanroom without any special measures necessary to accommodate electronic device fabrication using radioactive semiconductor materials. The electrically inactive betavoltaic battery device (e.g., 100A) may then be transported to another location for irradiation to transform at least some of a stable isotope to a radionuclide, resulting in the electrically active betavoltaic battery (e.g., 100B, 100C).

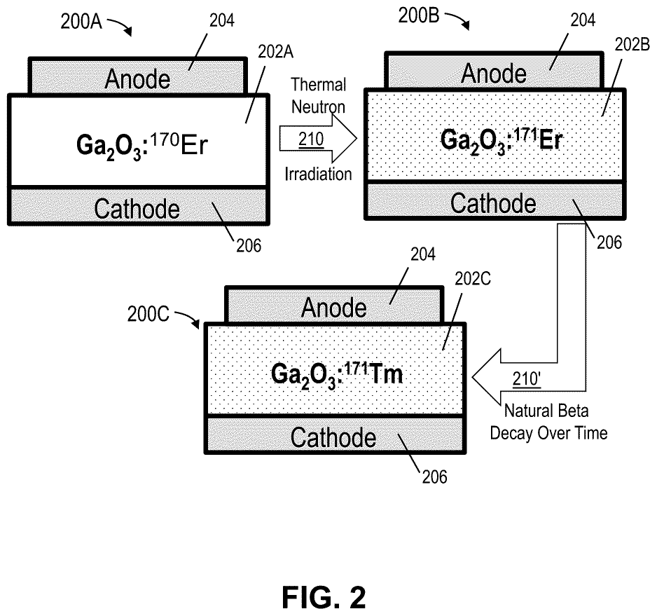

FIG. 2 shows the device and battery of FIG. 1 in accordance with embodiments of the invention, wherein the semiconductor is gallium (III) oxide. The exemplary electrically inactive betavoltaic battery device 200A includes at least one semiconductor material 202A comprising Ga₂O₃ doped with the stable isotope ¹⁷⁰Er and at least one diode comprising at least one anode 204, and at least one cathode 206. In implementations, the electrically inactive betavoltaic battery device 200A is exposed to thermal neutron irradiation at 210, which converts at least a portion of the ¹⁷⁰Er in the semiconductor material 202A to the first unstable isotope (radionuclide)¹⁷¹Er, resulting in the electrically active (intermediate) betavoltaic battery 200B including an emissive Ga₂O₃ substrate 202B. The ¹⁷¹Er doped semiconductor 202B is allowed to decay naturally via beta decay at 210′, which results in the ¹⁷¹Er decaying to the second radionuclide ¹⁷¹Tm. This results in a final active betavoltaic battery 200C, including the emissive semiconductor material 202C. Electron-hole pair generation originates from in situ beta particle emission within the semiconductor Ga₂O₃ crystal, which acts both as an electron emitter and an absorber simultaneously. Rather than an ex-situ deposited beta irradiation coating over the semiconductor absorber layer, embodiments of the invention leverage intentional dopants and/or unintentional impurities within a large-volume bulk Ga₂O₃ crystal.

The term radionuclide refers to a nuclide that has excess nuclear energy, making it unstable. This excess energy may be: emitted from the nucleus as gamma radiation; transferred to one of its electrons to release the energy as a conversion electron; or used to create and emit a new particle from the nucleus. In implementations, second and subsequent irradiation of the electrically active betavoltaic battery may be implemented to generate a recharged electrically active betavoltaic battery via the same mechanism, as will be discussed in more detail below. Although the exemplary electrically inactive betavoltaic battery device 200C utilizes Ga₂O₃ as a host crystal for the stable isotope, it should be understood that embodiments of the invention may utilize different semiconductor materials or host crystals and/or stable isotopes, and the invention is not intended to be limited to the examples described herein.

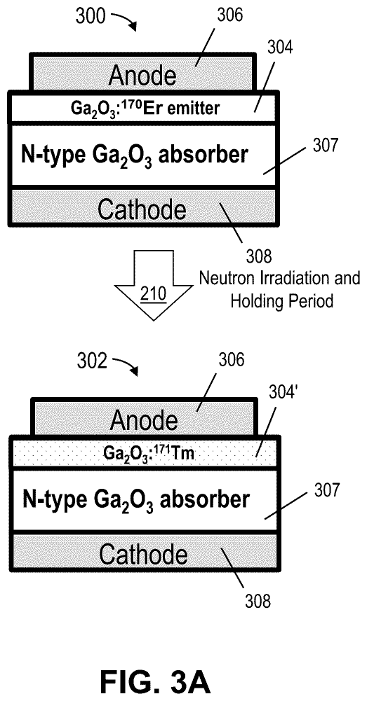

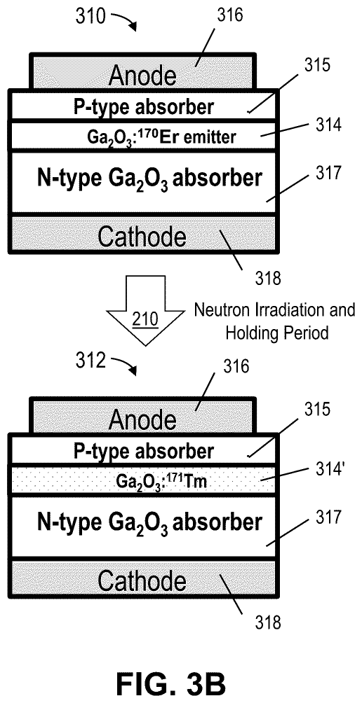

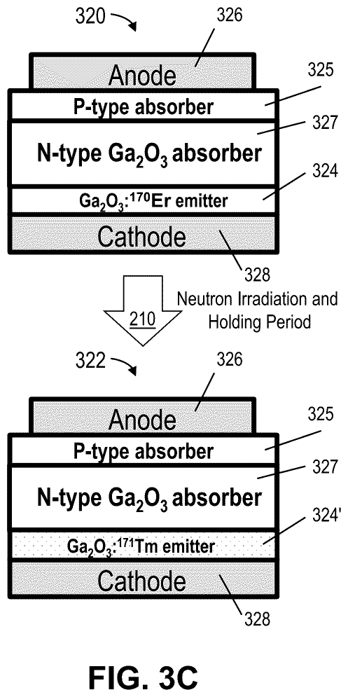

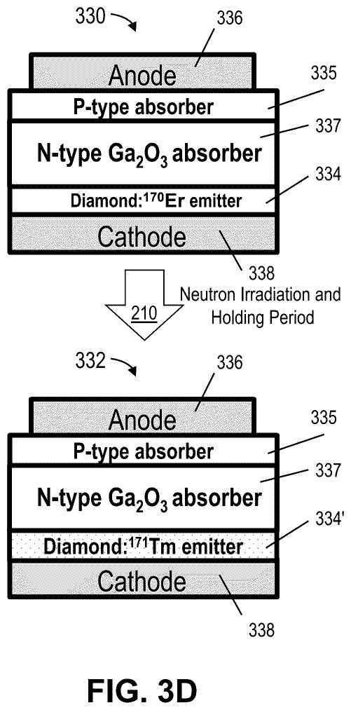

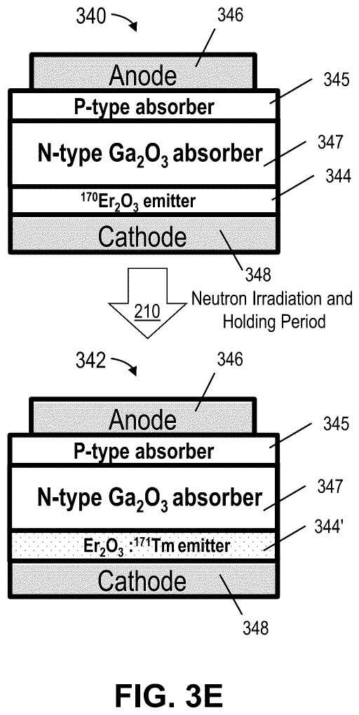

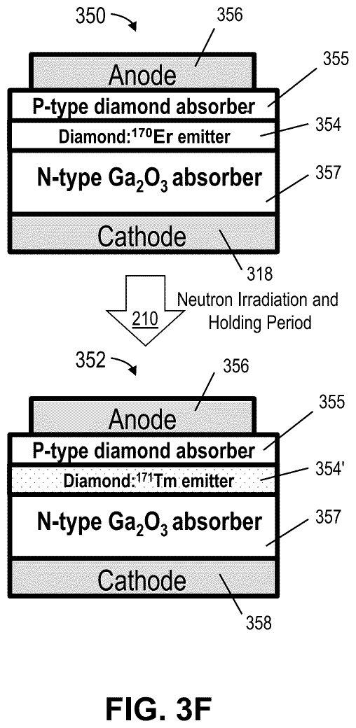

FIGS. 3A-3F show alternative embodiments of the inactive betavoltaic battery device and active betavoltaic battery of FIG. 2. More specifically, FIG. 3A depicts an electrically inactive betavoltaic battery device 300 in accordance with embodiments of the invention, including: a first semiconductor layer 304 comprising Ga₂O₃ doped with ¹⁷⁰Er, at least one diode comprising at least one anode 306 and at least one cathode 308, and a second semiconductor layer 307 comprising N-type Ga₂O₃ (an electron absorbing layer, a.k.a., absorber). In implementations, the electrically inactive betavoltaic battery device 300 is exposed to thermal neutron irradiation 210, which converts at least a portion of the ¹⁷⁰Er in the first semiconductor layer 304 to the radioisotope ¹⁷¹Er. After a period of time, natural beta decay results in an electrically active betavoltaic battery 302 including an electron (beta particle) emissive first semiconductor layer 304′ doped with the radioisotope ¹⁷¹Tm (an electron emitting and absorbing layer) adjacent an electron-absorbing semiconductor layer (absorber layer) 307.

FIG. 3B depicts an electrically inactive betavoltaic battery device 310 in accordance with embodiments of the invention, including: a first semiconductor layer 314 comprising Ga₂O₃ doped with ¹⁷⁰Er, at least one diode comprising at least one anode 316 and at least one cathode 318, a second semiconductor layer 317 comprising N-type Ga₂O₃ (a first electron absorbing layer), and a third semiconductor layer 315 comprising a P-type semiconductor material (a second electron absorbing layer). In implementations, the electrically inactive betavoltaic battery device 310 is exposed to thermal neutron irradiation 210, which converts at least a portion of the ¹⁷⁰Er in the first semiconductor layer 314 to the radioisotope ¹⁷¹Er, which then decays to the radioisotope ¹⁷¹Tm, resulting in an electrically active betavoltaic battery 312 including an electron (beta particle) emissive first semiconductor layer 314′ (an electron emitting and absorbing layer) between the first and second electron absorbing layers (absorber layers) 315 and 317.

FIG. 3C depicts an electrically inactive betavoltaic battery device 320 in accordance with embodiments of the invention, including: a first semiconductor layer 324 comprising Ga₂O₃ doped with ¹⁷⁰Er, at least one diode comprising at least one anode 326 and at least one cathode 328, a second semiconductor layer 325 comprising a P-type semiconductor material (a first electron absorbing layer), and a second semiconductor layer 327 comprising N-type Ga₂O₃ (a second electron absorbing layer). In the example shown, the first semiconductor layer 324 is positioned below the first and second electron absorbing layers (absorber layers 325 and 327). In implementations, the electrically inactive betavoltaic battery device 320 is exposed to thermal neutron irradiation 210, which converts at least a portion of the ¹⁷⁰Er in the first semiconductor layer 324 to the radioisotope ¹⁷¹Er, which then decays to the radioisotope ¹⁷¹Tm, resulting in an electrically active betavoltaic battery 322 including an electron (beta particle) emissive first semiconductor layer 324′ (an electron emitting and absorbing layer).

FIG. 3D depicts an electrically inactive betavoltaic battery device 330 in accordance with embodiments of the invention, including: a first semiconductor layer 334 comprising diamond doped with ¹⁷⁰Er, at least one diode comprising at least one anode 336 and at least one cathode 338, a second semiconductor layer 335 comprising a P-type semiconductor material (a first electron absorbing layer), and a third semiconductor layer 337 comprising N-type Ga₂O₃ (a second electron absorbing layer). In the example shown, the first semiconductor layer 334 is positioned below the first and second electron absorbing layers (absorber layers 335 and 337). In implementations, the electrically inactive betavoltaic battery device 330 is exposed to thermal neutron irradiation 210, which converts at least a portion of the ¹⁷⁰Er in the first semiconductor layer 334 to the radioisotope ¹⁷¹Er, which then decays to the radioisotope ¹⁷¹Tm, resulting in an electrically active betavoltaic battery 332 including an electron (beta particle) emissive first semiconductor layer 334′ (a beta particle emitting and absorbing layer).

FIG. 3E depicts an electrically inactive betavoltaic battery device 340 in accordance with embodiments of the invention, including: a first semiconductor layer 344 comprising erbium(III) oxide (Er₂O₃) including ¹⁷⁰Er, at least one diode comprising at least one anode 346 and at least one cathode 348, a second semiconductor layer 345 comprising a P-type semiconductor material (a first electron absorbing layer), and a third semiconductor layer 347 comprising N-type Ga₂O₃ (a second electron absorbing layer). Typically, the Er₂O₃ will have a natural abundance of ¹⁷⁰Er of about 14.9%. In the example shown, the first semiconductor layer 344 is positioned below the first and second electron absorbing layers (absorber layers 345 and 347). In implementations, the electrically inactive betavoltaic battery device 340 is exposed to thermal neutron irradiation 210, which converts at least a portion of the ¹⁷⁰Er in the first semiconductor layer 344 to the radioisotope ¹⁷¹Er, which then decays to the radioisotope ¹⁷¹Tm with a 7.5 h half-life, resulting in an Er₂O₃:¹⁷¹Tm doped emitter 344′ in an electrically active betavoltaic battery 342.

FIG. 3F depicts an electrically inactive betavoltaic battery device 350 in accordance with embodiments of the invention, including: a first semiconductor layer 354 comprising diamond including ¹⁷⁰Er, at least one diode comprising at least one anode 356 and at least one cathode 358, a second semiconductor layer 355 comprising a P-type diamond material (a first electron absorbing layer), and a third semiconductor layer 357 comprising N-type Ga₂O₃ (a second electron absorbing layer). In the example shown, the first semiconductor layer 354 is positioned between the first and second electron absorbing layers (absorber layers 355 and 357). In implementations, the electrically inactive betavoltaic battery device 350 is exposed to thermal neutron irradiation 210, which converts at least a portion of the ¹⁷⁰Er in the first semiconductor layer 354 to the radioisotope ¹⁷¹Er, which then decays to the radioisotope ¹⁷¹Tm, resulting in an electrically active betavoltaic battery 352 including an electron (beta particle) emissive first semiconductor layer 354′ (an electron emitting and absorbing layer).

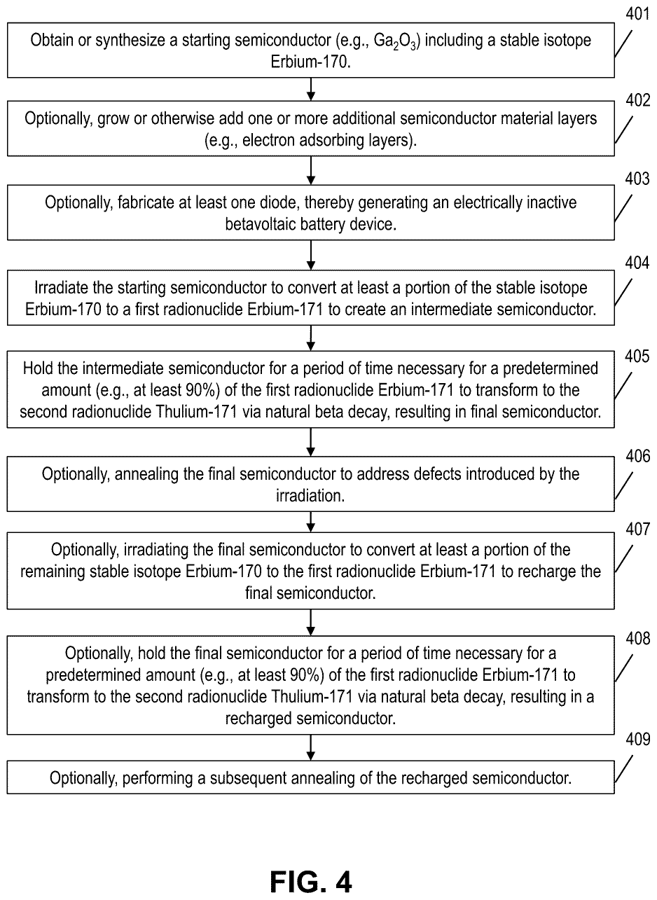

FIG. 4 shows a flowchart of an exemplary method in accordance with aspects of the present invention. Steps of the method may be carried out in the environment of FIG. 1 and are described with reference to elements depicted in FIG. 1 for exemplary purposes.

At 401, a starting semiconductor 102A is obtained or synthesized, wherein the semiconductor 102A is doped with the stable isotope ¹⁷⁰Er. The semiconductor 102A may comprise one or more layers of semiconductor material(s). In embodiments the semiconductor 102A is an ultrawide-bandgap semiconductor material. In aspects of the invention, the semiconductor 102A includes one or more semiconductor layers doped with the stable isotope ¹⁷⁰Er selected from: diamond, erbium oxide (Er₂O₃), aluminum nitride (AlN), aluminum gallium nitride (AlGaN), gallium nitride (GaN), silicon carbide (SiC), Ga₂O₃, sapphire (Al₂O₃), aluminum gallium oxide ((AlₓGa₁₋ₓ)₂O₃), zinc oxide (ZnO), and silicon (Si).

In embodiments the semiconductor 102A comprises a layer of Ga₂O₃ doped with ¹⁷¹Er. In implementations, the Ga₂O₃ is grown from a melt source using edge-defined film-fed growth (EFG) and Czochralski growth methods. In other implementations, iridium-free Ga₂O₃ is grown via Float Zone and Vertical Bridgman methods. The source of the ¹⁷⁰Er may be naturally occurring erbium oxide (Er₂O₃), or isotopically pure ¹⁷⁰Er. In implementations, isotopically pure Er or Er₂O₃ is alloyed into host Ga₂O₃ crystal during the Ga₂O₃ crystal growth process.

Optionally, at 402, one or more additional semiconductor material layers may be added to the starting semiconductor 102A. In implementations, at least one N-type and/or P-type electron absorber layer is added to the starting semiconductor device 100A. This step may be performed before or after irradiation at step 404. In implementations, the starting semiconductor 102A includes at least one additional semiconductor layer configured to act as an electron absorber. The additional semiconductor layer may be selected from Ga₂O₃, alloys of Ga₂O₃, diamond, Er₂O₃, Tm₂O₃, other rare earth oxides, GaN, alloys of GaN with Al, In, Sc, B, or combinations thereof, SiC, AlN, sapphire (Al₂O₃), ZnO, Si, Ge, or other semiconductors appropriate for the stable isotope utilized in this invention. In embodiments, one or more diodes are incorporated with the semiconductor 102A to produce the starting semiconductor device 100A. In implementations, a P-type absorber layer is present and is selected from: P-type Si, diamond, GaN, AlGaN, AlN, SiC, nickel oxide (NiO), chromium oxide (Cr₂O₃), chromium manganate (Cr₂MnO₄), cuprous oxide (CuO, Cu₂O, etc.), and other suitable P-type semiconductors.

Optionally, at 403, one or more diodes are added to the starting semiconductor 102A, thereby creating an electrically inactive betavoltaic battery device 102A. In implementations, an anode 104 and a cathode 106 are added at 403. This step may be performed before or after irradiation at step 404. In aspects of the invention the diodes includes an anode 104 fabricated on a first surface of the semiconductor 102A, and a cathode 106 fabricated on a second surface of the semiconductor 102A.

At 404, the starting semiconductor 102A (optionally with additional semiconductor material layers and/or at least one diode) is irradiated with thermal neutron radiation to convert at least a portion of the stable isotope ¹⁷⁰Er to the first radionuclide ¹⁷¹Er, resulting in an intermediate semiconductor 102B. In implementations, an entire semiconductor device 100A is irradiated at 404, resulting in the intermediate betavoltaic battery device 102B.

At 405, the intermediate semiconductor 102B is held for a period of time necessary for a predetermined amount (e.g., at least 90%) of the first radionuclide ¹⁷¹Er to transform to the second radionuclide ¹⁷¹Tm via natural beta decay, thereby resulting in the ¹⁷¹Tm-doped semiconductor 102C. In implementations, the intermediate semiconductor device 100B converts to an active betavoltaic battery 100C over the period of time at 405.

Optionally, at 406, the semiconductor 102C is annealed to address defects introduced into the semiconductor during irradiation at 404. In implementations, the active betavoltaic battery 100C is annealed at 406.

Optionally, at 407, the semiconductor 102C is irradiated again to convert at least a portion of the remaining stable isotope ¹⁷⁰Er to the first radionuclide ¹⁷¹Er, in order to recharge the semiconductor 102C.

Optionally, at 408, the semiconductor 102C is held for a period of time necessary for a predetermined amount (e.g., at least 90%) of the first radionuclide ¹⁷¹Er generated at step 407 to transform to the second radionuclide ¹⁷¹Tm via natural beta decay, resulting in a recharged semiconductor.

Optionally, at 409, subsequent annealing of the recharged semiconductor is performed to address defects introduced into the semiconductor during irradiation at step 407.

Unlike prior betavoltaic devices which rely on beta particle (electron) emission from an emitter layer deposited on a separate semiconductor absorber layer or device (typically a P-N junction), implementations of the invention result in a semiconductor layer 102C that acts as both an electron emitter and an electron absorber.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method comprising:
providing a starting semiconductor including a semiconductor material layer doped with a stable non-radioactive isotope erbium-170;
irradiating the starting semiconductor with thermal neutrons, thereby causing conversion of at least a portion of the stable non-radioactive isotope erbium-170 to a radioisotope erbium-171, resulting in an intermediate semiconductor; and
holding the intermediate semiconductor in a radiation safe environment for a period of time necessary for a predetermined amount of the erbium-171 to transform to a radionuclide thulium-171 via natural beta decay, thereby resulting in a final semiconductor, wherein the semiconductor material layer acts as both an electron emitter and an electron absorber simultaneously.

2. The method of claim 1, wherein the source of the erbium-170 is erbium(III) oxide (Er₂O₃).

3. The method of claim 1, wherein the source of the erbium-170 is isotopically pure erbium or naturally occurring erbium.

4. The method of claim 1, wherein the semiconductor material layer is selected from the group consisting of: diamond, erbium oxide (Er₂O₃), aluminum nitride (AlN), aluminum gallium nitride (AlGaN), gallium nitride (GaN), silicon carbide (SiC), gallium oxide (Ga₂O₃), sapphire (Al₂O₃), aluminum gallium oxide ((AlₓGa₁₋ₓ)₂O₃), zinc oxide (ZnO), and silicon (Si).

5. The method of claim 4, wherein the semiconductor material layer comprises beta gallium oxide (β-Ga₂O₃), and the method further comprises growing the semiconductor material layer with the stable non-radioactive isotope erbium-170.

6. The method of claim 4, wherein the semiconductor material layer comprises iridium-free β-gallium oxide (β-Ga₂O₃).

7. The method of claim 1, wherein the semiconductor material layer is within a semiconductor device including one or more diodes.

8. The method of claim 7, wherein the one or more diodes comprise an anode fabricated at a first surface of the semiconductor material layer and a cathode fabricated at a second surface of the semiconductor material layer.

9. The method of claim 1, further comprising annealing the final semiconductor to repair crystal damage in the semiconductor material layer caused by the irradiation.

10. The method of claim 1, wherein the starting semiconductor includes one or more additional layers, different from the semiconductor material layer, that act as electron absorbers.

11. The method of claim 10, where the starting semiconductor includes an N-type electron absorber layer of gallium nitride.

12. An electrically inactive betavoltaic battery device comprising:
a semiconductor material layer including a stable non-radioactive isotope erbium-170, and
one or more diodes incorporating the semiconductor material layer, wherein the electrically inactive betavoltaic battery device is configured to be transformed into an electrically active betavoltaic battery upon irradiation with thermal neutrons.

13. The electrically inactive betavoltaic battery device of claim 12, wherein the semiconductor material layer is selected from the group consisting of: diamond, erbium oxide (Er₂O₃), aluminum nitride (AlN), aluminum gallium nitride (AlGaN), gallium nitride (GaN), silicon carbide (SiC), gallium oxide (Ga₂O₃), sapphire (Al₂O₃), aluminum gallium oxide ((AlₓGa₁₋ₓ)₂O₃), zinc oxide (ZnO), and silicon (Si).

14. The electrically inactive betavoltaic battery device of claim 12, wherein the semiconductor material layer comprises beta-gallium oxide (β-Ga₂O₃).

15. The electrically inactive betavoltaic batter device of claim 12, further comprising an N-type electron absorber layer.

16. The electrically inactive betavoltaic batter device of claim 12, further comprising a P-type absorber layer.

17. A betavoltaic battery device comprising:
a semiconductor material layer including a radioactive isotope thulium-171, and
one or more diodes incorporating the semiconductor material layer, wherein the semiconductor material layer acts as both an electron emitter and an electron absorber simultaneously.

18. The betavoltaic battery device of claim 17, wherein the semiconductor material layer is selected from the group consisting of: diamond, erbium oxide (Er₂O₃), aluminum nitride (AlN), aluminum gallium nitride (AlGaN), gallium nitride (GaN), silicon carbide (SiC), gallium oxide (Ga₂O₃), sapphire (Al₂O₃), aluminum gallium oxide ((AlₓGa₁₋ₓ)₂O₃), zinc oxide (ZnO), and silicon (Si).

19. The betavoltaic battery device of claim 17, wherein the semiconductor material layer comprises β-gallium oxide (β-Ga₂O₃).

20. The betavoltaic battery device of claim 17, further comprising at least one N-type or P-type absorber layer.
